(19) United States
(12) Patent Application Publication
(10) Pub. No.: US 2025/0210359 A1
(43) Pub. Date: Jun. 26, 2025

(54) METHOD FOR MANUFACTURING A SEMICONDUCTOR DEVICE AND SEMICONDUCTOR DEVICE

(71) Applicant: Fraunhofer-Gesellschaft zur Förderung der angewandten Forschung e.V., München (DE)

(72) Inventors: Frank DIETZ, Itzehoe (DE); Michael MENSING, Itzehoe (DE); Heiko ZÜGE, Itzehoe (DE)

(73) Assignee: Fraunhofer-Gesellschaft zur Förderung der angewandten Forschung e.V., München (DE)

(21) Appl. No.: 19/067,894

(22) Filed: Mar. 1, 2025

Related U.S. Application Data
(63) Continuation of application No. PCT/EP2023/073821, filed on Aug. 30, 2023.

(30) Foreign Application Priority Data
Sep. 1, 2022 (DE) 10 2022 209 112.4

(51) Int. Cl. H01L 21/285; H10D 30/47; H10D 64/01

(52) U.S. Cl. CPC H01L 21/28575; H10D 64/01; H10D 30/471

(57) ABSTRACT

A method for manufacturing a semiconductor device comprising: providing a layered structure of the semiconductor device, the layered structure comprising a first layer, the first layer comprising a III-V compound semiconductor material; depositing a second layer on a main surface region of the first layer such that the second layer comprises silicon and a doping material for the silicon; activating the second layer to form an ohmic contact between the first layer and the second layer.

### CROSS-REFERENCE TO RELATED APPLICATIONS

This application is a continuation of copending International Application No. PCT/EP2023/073821, filed Aug. 30, 2023, which is incorporated herein by reference in its entirety, and additionally claims priority from German Application No. 10 2022 209 112., filed Sep. 1, 2022, which is also incorporated herein by reference in its entirety.

Embodiments of the invention relate to a method for manufacturing a semiconductor device. Further embodiments relate to semiconductor devices. In particular, embodiments relate to forming an ohmic contact to a III-V compound semiconductor.

### BACKGROUND OF THE INVENTION

III-V compound semiconductors, for example gallium nitride, GaN, are used as the functional basis, i.e. as active layer, of semiconductor devices, for example in field-effect transistors, in particular in high electron mobility transistors (HEMT), or in PN diodes. An ohmic contact for contacting an active layer of a III-V compound semiconductor has so far been manufactured by means of a metallization stack, i.e. a layered stack consisting of a combination of different metals, and its alloy. However, depositing and alloying the metals can limit the compatibility with other manufacturing methods, particularly CMOS technology. In particular, the metals can cause undesirable impurities.

Further, US 2022/115525 A1 and US 2019/0115448 A1 each describe a HEMT in which metal or doped poly-silicon is used for contacting. In the article “Novel Poly-Si/GaN Vertical Heterojunction Diode”, Emori et al, Materials Science Forum Vols. 821-823 (2015) pp 1015-1018, a junction between n(+)-type poly-silicon and n(−)-type GaN with a doping of 2×10¹⁶ cm⁻³ is also described.

It would be desirable to have a method for manufacturing a semiconductor device that allows the formation of a contact with ohmic characteristic and low contact resistance with little effort and extensive compatibility with further manufacturing steps, in particular with CMOS technology.

### SUMMARY

According to an embodiment, a method for manufacturing a semiconductor device may have the steps of: providing a layered structure of the semiconductor device, the layered structure comprising a first layer, the first layer comprising a III-V compound semiconductor material; depositing a second layer on a main surface region of the first layer, such that the second layer comprises silicon and a doping material for the silicon, wherein depositing the second layer is performed using chemical vapor deposition or physical vapor deposition; activating the second layer to form an ohmic contact between the first layer and the second layer, wherein depositing the second layer is performed such that introducing the doping material into the silicon is performed during depositing the silicon on the main surface region of the first layer.

Another embodiment may have a semiconductor device manufactured using the inventive method.

Embodiments of the present invention are based on the finding that a III-V compound semiconductor can be contacted by means of doped silicon, in particular highly doped silicon, such that an ohmic contact is formed between the III-V compound semiconductor and the doped silicon. The formation of the ohmic contact is obtained in particular by activating the layer comprising the doped silicon. The use of doped silicon for contacting the III-V-compound semiconductor, which can form a functional basis or an active layer of the semiconductor device to be manufactured, offers the advantage over the use of metals or metallization stacks that contamination of the surface with metal can be avoided during the manufacturing process. This can occur in particular during the needed alloying of the metallization stacks. By using doped silicon, the inventive method can be particularly suitable for integration in CMOS processes. In addition, the use of doped silicon instead of metals can simplify the manufacturing process, since the structuring of silicon can be implemented more easily, for example by etching processes, compared to metals, which are generally structured by means of lift-off methods.

Embodiments of the invention provide a method for manufacturing a semiconductor device, for example a microelectronic device, a power electronic device, or a MEMS (micro-electromechanical system) device. The method comprises a step of providing a layered structure of the semiconductor device, the layered structure comprising a first layer, the first layer comprising a III-V compound semiconductor material, e.g. a material of a III-V compound semiconductor, e.g. GaN, AlGaN, AlN. For example, the III-V compound semiconductor material can be doped. In examples, the first layer can comprise, i.e. essentially consist of, the III-V compound semiconductor material, e.g. the doped III-V compound semiconductor material, i.e. apart from impurities. The method further comprises a step of depositing a second layer on a main surface region of the first layer, such that the second layer comprises silicon and a doping material for the silicon. For example, depositing is performed such that the second layer covers the first layer at least partially. The method further comprises a step of activating, e.g. tempering or annealing, the second layer to form an ohmic contact between the first layer and the second layer.

In other words, the second layer with the doped silicon can be deposited directly on the first layer with the III-V compound semiconductor material. Depositing a layered stack or depositing intermediate layers can therefore be avoided. This makes the manufacturing process simple. By activating the second layer, in particular the doped silicon in the second layer, an ohmic contact can be formed between the second layer and the III-V-compound semiconductor material, in particular with a particularly low contact resistance. Doped silicon can in turn be contacted ohmically using conventional methods, for example by depositing a metal on the second layer, so that the disclosed method allows simple forming of an ohmic contact to the III-V compound semiconductor material of the first layer.

According to embodiments, depositing the second layer is performed such that introducing the doping material into the silicon is performed during depositing the silicon on the main surface region of the first layer. In other words, the silicon is doped in-situ. The in-situ doping of the silicon during depositing the silicon allows simple and fast manufacture of the second layer.

According to embodiments, the III-V compound semiconductor material of the first layer is doped with a doping material, wherein an atomic density of the doping material in the first layer is between 10¹⁷ cm⁻³ and 10²³ cm⁻³ or between 10¹⁸ cm⁻³ and 10²¹ cm⁻³. The first layer can therefore be conductive, or be formed such that the same can be switched to a conductive state. The III-V compound semiconductor material of the first layer can thus be a functional basis of the device, for example an active layer. Further, it has been found that a particularly low contact resistance between the first and the second layer can be achieved with a doping of more than 10¹⁷ cm⁻³ or more than 10¹⁸ cm⁻³.

According to embodiments, activating the second layer involves irradiating the layered structure with electromagnetic radiation. Heating the second layer can cause annealing of the silicon deposited together with the doping material. Irradiation with electromagnetic radiation can generate a large temporal temperature gradient in the second layer. It has been found that a particularly low contact resistance and an ohmic characteristic of the contact between the first and the second layer can be achieved. In particular, the irradiation with electromagnetic radiation can be precisely dosed, especially such that the heating takes place quickly in order to achieve a low contact resistance, but cracking in the second layer is prevented.

According to embodiments, activating the second layer is performed using a laser scanning method, for example with a pulsed laser. A laser scanning method can provide a high power density of electromagnetic radiation in order to generate a high temperature gradient.

According to embodiments, activating the second layer includes thermal heating, for example tempering, of the second layer. For example, thermal heating is performed by means of an oven or by means of an RTA (rapid thermal annealing) process. Thermal heating represents a good compromise between a simple process and extensive annealing of the doped silicon, and thus achieving low contact resistance.

According to embodiments, depositing the second layer takes place such that the silicon of the second layer is amorphous or polycrystalline. It has been found that in particular amorphous or polycrystalline silicon is suitable for forming an ohmic contact with the III-V compound semiconductor material.

According to embodiments, depositing the second layer, e.g. including depositing the silicon together with the doping material, takes place using chemical vapor deposition (CVD) or physical vapor deposition (PVD), e.g. by means of plasma-enhanced CVD (PECVD) or low-pressure CVD (LPCVD). By means of vapor deposition, the silicon can be doped in-situ during deposition, wherein it can be deposited amorphous or polycrystalline. It has been found that with such in-situ doped amorphous or polycrystalline silicon layers, an ohmic contact with a particularly low contact resistance can be achieved through subsequent activation.

According to embodiments, the method further comprises the step of: forming a contact structure on a main surface region facing away from the first layer (e.g., a non-necessarily contiguous region on a main surface of the first layer facing away from the first layer) of the second layer, wherein forming the contact structure comprises depositing one or several further layers on the main surface region of the second layer. For example, depositing the further layers takes place to form an ohmic contact between the second layer and the contact structure (e.g., between the second layer and a main surface region of the contact structure facing away from the second layer). Together with an ohmic contact between the first and the second layer, an ohmic contact can therefore be formed between the first layer and the contact structure, so that the first layer can be contacted ohmically via the contact structure.

According to embodiments, depositing the second layer takes place such that a concentration of a doping material for the silicon in the second layer is greater than 10¹⁵ cm⁻³, advantageously greater than 10¹⁶ cm⁻³, more advantageously greater than 10¹⁷ cm⁻³, or is in a range between 10¹⁵ cm⁻³ and 10²³ cm⁻³, advantageously between 10¹⁷ cm⁻³ and 10²³ cm⁻³. A particularly low contact resistance between the first layer and the second layer can be obtained by high doping of the silicon.

According to embodiments, the III-V compound semiconductor material of the first layer comprises an n-type doping and the doping material of the second layer generates an n-type doping of the silicon. Alternatively, the III-V compound semiconductor material of the first layer comprises a p-type doping and the doping material of the second layer generates a p-type doping of the silicon. The n-type/n-type or p-type/p-type combinations for the first and second layers are particularly suitable for forming an ohmic contact between the first and second layers.

Further embodiments provide a semiconductor device manufactured by the method described above.

### BRIEF DESCRIPTION OF THE DRAWINGS

Embodiments of the present invention will be detailed subsequently referring to the appended drawings, in which:

FIG. 1 shows a flowchart of a method for manufacturing a semiconductor device according to an embodiment,

FIG. 2A, B each illustrate a semiconductor device according to an embodiment,

FIG. 3 illustrates a semiconductor device according to a further embodiment,

FIG. 4 illustrates an HEMT according to an embodiment,

FIG. 5 illustrates a vertical diode according to an embodiment.

### DETAILED DESCRIPTION OF THE INVENTION

In the following, embodiments of the present disclosure will be described in detail using the accompanying descriptions. In the following description, many details are described in order to provide a more thorough explanation of embodiments of the disclosure. However, it is apparent to those skilled in the art that other embodiments can be implemented without these specific details. Features of the various embodiments described can be combined with each other, unless features of a respective combination are mutually exclusive or such combination is expressly excluded.

It should be noted that the same or similar elements or elements having the same functionality can be provided with the same or similar reference numbers or can be labeled the same, wherein a repeated description of elements provided with the same or similar reference numbers or labeled the same is typically omitted. Descriptions of elements that have the same or similar reference numbers or are labeled the same are interchangeable.

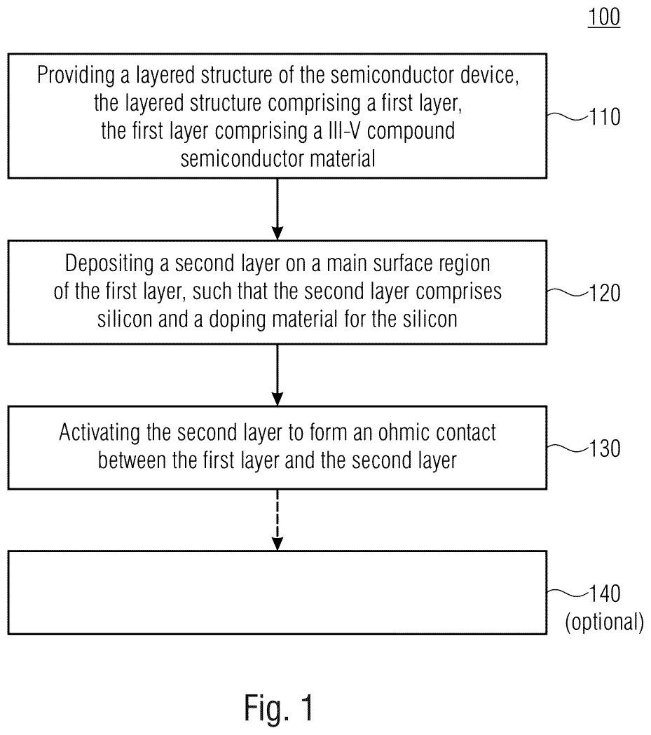

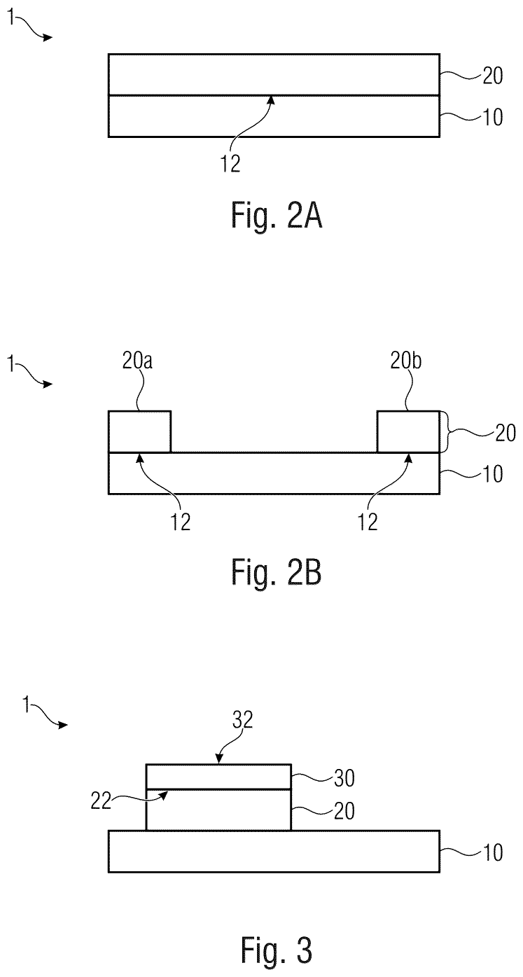

FIG. 1 shows a flow diagram of a method 100 for manufacturing a semiconductor device according to an embodiment. FIG. 2A shows a schematic illustration of a semiconductor device 1 manufactured by means of the method 100 according to an embodiment. The method 100 according to FIG. 1 will be explained below with reference to the semiconductor device 1 illustrated in FIG. 2.

The method 100 comprises a step 110. In step 110, a layered structure of the semiconductor device is provided, which comprises a first layer 10. Optionally, the layered structure can comprise further layers. The first layer 10 comprises a III-V compound semiconductor material. In examples, the first layer can consist of the III-V compound semiconductor material. That is, the first layer can consist of the III-V compound semiconductor material apart from impurities, i.e. unintentional impurities, wherein the III-V compound semiconductor material can optionally comprise a doping material. That is, in examples, the first layer can consist of a III-V compound semiconductor material doped with a doping material.

The method 100 further comprises a step 120. In step 120, a second layer 20 is deposited on a main surface region 12 of the first layer 10. Depositing is performed such that the second layer comprises silicon and a doping material for the silicon. Thus, by depositing the first layer 10 on the second layer 20, the second layer is disposed adjacent to the first layer. In examples, the second layer can consist (e.g. essentially) of the silicon and the doping material.

Further, the method 100 has a step 130. In step 130, the second layer 20 is activated to form an ohmic contact between the first layer and the second layer.

For example, activating 130 can involve annealing the silicon with the doping material. For this purpose, the second layer 130 can be heated or tempered. Activating can result in the formation of an ohmic contact between the first layer and the second layer. Thus, after step 130, an ohmic contact can exist between the first layer 10 and the second layer 20.

The first layer 10 can, for example, be a functional basis of the semiconductor device. For example, the first layer 10 can be an active layer of the semiconductor device. For example, the first layer 10 can be configured such that it provides a conduit at least in an operative state of the semiconductor device, i.e. that the same is electrically conductive.

Through an ohmic contact between the first layer and the second layer, the first layer can be electrically connected or contacted by electrically contacting the second layer 20. Forming an ohmic contact to doped silicon is again possible with a metal layer, wherein, in contrast to direct contacting of the III-V compound semiconductor with metal, no complex metallization stacks and no alloy are needed. Thus, by manufacturing the doped and activated silicon layer according to the method 100, an ohmic contact to the III-V compound semiconductor of the first layer 10 can be established, avoiding the manufacture of a costly metallization stack and avoiding contamination of the semiconductor device by an alloy of the metallization stack. As a result, the method 100 can be designed to be CMOS-compatible in contrast to conventional methods for contacting III-V compound semiconductors.

According to embodiments, the method 100 is CMOS-compatible. According to embodiments, the method 100 is part of a CMOS process.

In the following, optional details of the semiconductor device 10 will be described, which can characterize the method 100 in that the steps of the method are carried out accordingly.

A layered structure is, for example, a structure that comprises one or several layers, wherein the layers are arranged along a stacking direction and each extends in a plane perpendicular to this stacking direction. Each layer of the layered structure can comprise, for example, two opposing main surfaces which extend perpendicular to this stacking direction. The main surfaces can be connected by secondary surfaces. A main surface can be composed of several main surface regions, which are not necessarily connected. In other words, in examples, a layer of the layered structure can be formed by several contiguous or non-contiguous parts whose main surface regions can lie, for example, but not necessarily, in a common plane.

For example, the stacking direction along which the plurality of layers are arranged is parallel to a surface normal of a layer. A direction perpendicular to the surface normal of a layer of the layered structure can be referred to, for example, as a lateral direction or as a direction parallel to the layered structure or as a direction parallel to one of the plurality of layers of the layered structure

The layered structure can be characterized, for example, by the fact that two of its layers are separated from each other by at least one interface. The interface between two adjacent layers of the layered structure can therefore be formed by the main surfaces of the two layers facing each other. An interface can therefore represent a transition between a material of one layer of the layered structure and a material of the adjacent layer of the layered structure.

In the example shown in FIG. 2A, the main surface region 12 of the first layer 10, on which the second layer 20 is deposited, completely includes a main surface of the first layer 10. In other examples, the main surface region 12 comprises only a part of the main surface of the first layer 10. Further, the main surface region 12 can be configured contiguously or can comprise several subregions. In FIG. 2B, a further example is shown in which the main surface region 12 comprises two subregions.

In examples, the second layer 20 is therefore deposited on the first layer 10 in areas. In FIG. 2A, the second layer 20 comprises the exemplary number of two subareas 20a and 20b.

In examples, depositing the second layer 20 can take place in areas in order to provide the subareas. In other examples, the second layer 20 can be structured after depositing, for example by etching.

According to embodiments, step 120 is performed such that the doping material for the silicon of the second layer is introduced into the silicon while depositing the silicon on the first layer 10. In other words, the silicon and the doping material for the silicon are deposited on the first layer at the same time.

According to embodiments, the doping material for the silicon of the second layer 20 comprises one or several doping materials for silicon, in particular one or several of phosphorus, boron, antimony, magnesium, gallium, aluminum and arsenic. For example, the doping material is one of these materials, for example phosphorus.

According to embodiments, doping of the silicon of the second layer 20 is greater than 10¹⁵ cm⁻³ or greater than 10¹⁶ cm⁻³ or greater than 10¹⁷ cm⁻³, in particular greater than 10¹⁷ cm⁻³. For example, doping is in a range between 10¹⁵ cm⁻³ and 10²³ cm⁻³ or between 10¹⁶ cm⁻³ and 10²³ cm⁻³ or between 10¹⁷ cm⁻³ and 10²³ cm⁻³. Higher doping of the silicon can result in better conductivity and thus to a lower contact resistance for a contact to the first layer 10 via the silicon.

According to embodiments, the step 120 of depositing the second layer 20 can be performed by CVD or PVD, for example by PECVD or LPCVD.

According to embodiments, the silicon of the second layer 20 is amorphous or polycrystalline.

For example, the amorphous or polycrystalline silicon can be manufactured by depositing the second layer 20 by means of CVD or PVD.

According to embodiments, the III-V compound semiconductor material of the first layer 10 is doped, i.e. contains a doping material.

As already mentioned, the first layer can be an active layer of the semiconductor device and can be configured, for example, to be conductive at least in an operative state of the device. This can be achieved by doping the III-V compound semiconductor material.

According to embodiments, an atomic density of the doping material for the III-V compound semiconductor material in the first layer 10 is between 10¹⁷ cm⁻³ and 10²³ cm⁻³ or between 10¹⁸ cm⁻³ and 10²¹ cm⁻³.

It has been found that a contact with an ohmic characteristic and a particularly low contact resistance between the first and the second layer can be achieved by a doping of more than 10¹⁷ cm⁻³ (e.g. in particular with p-type doping). In particular for dopings of more than 10¹⁸ cm⁻³ (e.g. in particular for n-type doping), a particularly low contact resistance can be achieved.

According to embodiments, the III-V compound semiconductor material is, for example, GaN with a silicon or magnesium doping.

In examples, during activating 130, silicon atoms of the second layer can diffuse into an interface region of the first layer adjacent to the main surface region 12. This can result in increased doping of the III-V compound semiconductor in the interface region in examples, particularly in embodiments using silicon-doped GaN as III-V compound semiconductor material. The diffusion depth can be a few nm, e.g. less than 10 nm.

A layer thickness of the second layer can, for example, be in a range between 50 nm and 2000 nm, or in a range between 100 nm and 500 nm.

According to embodiments, the type (n-type or p-type) of doping of the silicon of the second layer 20 and the III-V compound semiconductor material of the first layer 10 is the same. Thus, for example, both the silicon and the III-V compound semiconductor material are n-type doped, for example, the silicon can be phosphorus doped and the III-V compound semiconductor material can be GaN with silicon doping. In another example, the doping material for the GaN can be germanium. Alternatively, both the silicon and the III-V compound semiconductor material can be p-type doped.

According to embodiments, the step 130 of activating is performed by irradiating the layered structure, for example the second layer 20, by means of electromagnetic radiation.

Using electromagnetic radiation, energy can be introduced directly into the second layer to heat the same in order to anneal the silicon with the doping material.

In examples, the electromagnetic radiation can be pulsed. A high power density can be achieved in the pulse, whereby rapid heating, i.e. a large temperature gradient over time, can be achieved. Faster heating can lead to a better result in terms of the ohmic characteristic and/or a low contact resistance of the contact between the first layer and the second layer.

According to embodiments, irradiation with electromagnetic radiation is performed using a laser scanning method.

A laser beam can be guided over the second layer to activate the same. For example, a pulsed laser beam can be focused on a position of the second layer and the position can be scanned via the second layer. This can be done such that neighboring positions overlap, for example.

As an alternative to irradiation with electromagnetic radiation, activating 130 can be performed by means of thermal heating, for example in an oven process, or in an RTA process. In examples of an RTA process, the heating of the second layer 20 can be performed by heating the first layer 10.

As shown in FIG. 1, the method 100 can optionally comprise a further step 140. In step 140, as illustrated in FIG. 3 according to an embodiment, a contact structure 30 is manufactured on a main surface region 22 of the second layer 20 facing away from the first layer 10. Here, one or several further layers are deposited on the main surface region 22 of the second layer. For example, a first further layer is deposited on the main surface region 22 of the second layer, and optionally one or several further layers are deposited on the first further layer.

For example, the contact structure is formed to establish ohmic contact between the second layer 20 and the contact structure 30 (e.g., between the second layer 20 and a main surface region 32 of the contact structure 30 facing away from the second layer). Thus, an ohmic contact can exist between the main surface region 32 of the contact structure and the first layer 10. To contact the first layer 10, the contact structure can then be bonded or soldered, for example.

In examples, the contact structure 30 consists of one or several metal layers, e.g. one or several of Au, Ti, Al.

According to embodiments, the semiconductor device 1 is a microelectronic device, a power electronic device or a MEMS device.

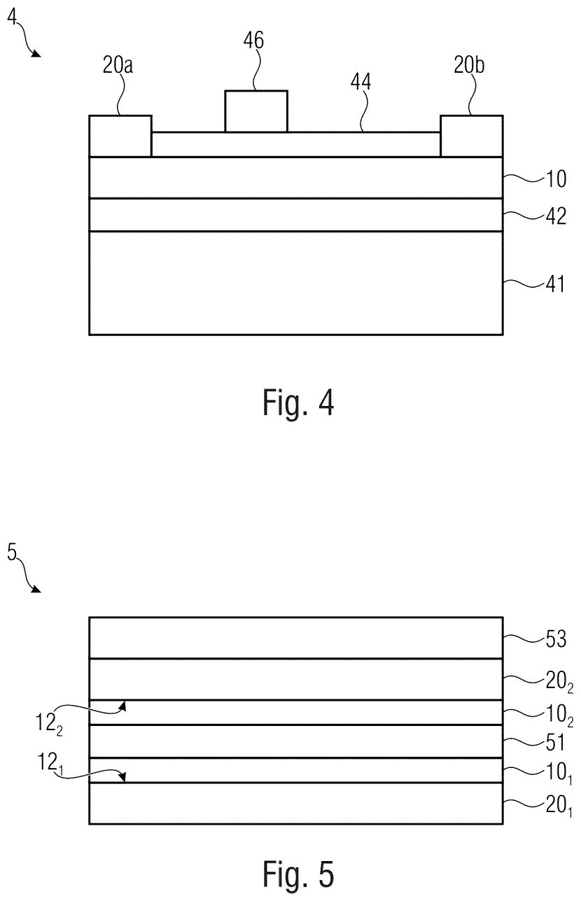

Embodiments of the invention relate to semiconductor devices manufactured by the method 100. Thus, the semiconductor devices 1, 4, 5 described in FIGS. 2A, 2B, and 3 and in FIGS. 4 and 5 described below also represent embodiments of the invention.

Examples of the semiconductor device 1 that can be manufactured using the method 100 are described below. However, other designs and types than those described below can also be manufactured using the method 100.

FIG. 4 shows a schematic representation of an HEMT 4 that can be manufactured by the method 100 according to an embodiment. The HEMT 4 can optionally be an example of the semiconductor device 1. In the HEMT 4, the second layer 20 comprises two subregions 20a and 20b, each of which can comprise an ohmic contact with the first layer 10. The two subareas 20a, 20b of the second layer can therefore act as source and drain contacts of the HEMT. The III-V compound semiconductor material of the second layer can be GaN, for example, doped GaN, or AlGaN, for example, or doped AlN, for example.

The first layer 10 can be disposed between a substrate 41 and the second layer 20. The substrate can be, for example, silicon, Qromis Substrate Technology (QST), alternative CTE-matched substrates or a III-V compound semiconductor material, for example GaN, or can comprise one of these materials. Optionally, a stress compensation layer 42 can be disposed between the substrate 41 and the first layer 10, which can alternatively be referred to as a lattice matching layer. The substrate 41 and the first layer 10 can each be disposed on one of two opposing main surface regions of the stress compensation layer 42.

The HEMT can further comprise a barrier layer 44, or junction layer 44, which is disposed adjacent to a main surface region of the second layer facing away from the first layer 10, for example between the two subareas 20a, 20b of the second layer 20. The barrier layer 44 can comprise, or consist of, a III-V compound semiconductor material. The III-V compound semiconductor material of the barrier layer 44 can be doped. For example, the III-V compound semiconductor material of the further layer 44 is AlN, which is doped with, for example, Ga, Sc, or In. The barrier layer 44 can be configured, e.g. with respect to the first layer 10, such that a two-dimensional electron gas, 2DEG, can form along an interface between the first layer 10 and the barrier layer 44, at least in an operative state of the HEMT 4, which provides a transport channel between the first subarea 20a, i.e. the source contact, and the second subarea 20b, i.e. the drain contact.

A contact structure 46 can be arranged adjacent to a main surface region of the barrier layer 44 facing away from the first layer 10.

The contact structure 46 can comprise, for example, doped silicon, such as doped amorphous or doped polycrystalline silicon. The contact structure can further comprise a diffusion barrier layer, for example arranged adjacent to the first layer 10. Alternatively or additionally, the contact structure can have one or several insulating layers which electrically insulate the silicon of the contact structure from the first layer.

Alternatively, the contact structure 46 can comprise a metal layer which forms a Schottky barrier at the interface between the contact structure 46 and the first layer.

The layered structure provided in step 110 of the method 100 can comprise the first layer 10, the substrate 41, and optionally the stress compensation layer 42, according to the example in FIG. 4. Further, the method can include manufacturing the barrier layer 44 and the contact structure 46. The source contact and the drain contact can be manufactured using steps 120, 130 as described above.

FIG. 5 shows a schematic illustration of a vertical diode 5 that can be manufactured by the method 100 according to an embodiment. The vertical diode comprises a first first layer 10₁ and a second first layer 10₂, both of which can be configured like the previously described first layer 10, wherein the first first layer 10₁ and the second first layer 10₂ have different doping types, so that they form a pn junction. Thus, the first first layer 10₁ has an n-type doping and the second first layer 10₂ has a p-type doping or vice versa. For example, the III-V compound semiconductor material of each of the layers 10₁ and 10₂ is GaN.

Optionally, an intermediate layer 51 with or made of a III-V compound semiconductor material can be arranged between the first first layer 101 and the second first layer 102, for example, apart from the doping, made of the same material as the layers 101 and 102. The intermediate layer 51 can be undoped or not intentionally doped.

A first second layer 20₁ is arranged adjacent to a main surface region 12₁ of the first first layer 10₁ facing away from the second first layer 10₂, and a second second layer 20₂ is arranged adjacent to a main surface region 12₂ of the second first layer 10₂ facing away from the first first layer 10₁. The first and second second layers 20₁, 20₂ can each be implemented or manufactured in the same way as the second layer 20 described above

The first second layer 20₁ can thus provide an ohmic contact to the first first layer 10₁ and the second second layer 20₂ can provide an ohmic contact to the second first layer 10₂.

Optionally, a further layer 53 can be arranged adjacent to one of the main surface regions of the first or the second second layer 20₁, 20₂ facing away from the first layers 10₁, 10₂. The further layer 53 can be a conductive substrate that is bonded or can be bonded. Alternatively or additionally, the layer 53 can provide mechanical stability. In examples, the layer 53 can correspond to the described contact structure 30.

Although some aspects of the present disclosure have been described as features related to a device, it is obvious that such a description can also be considered as a description of corresponding features of a method. Although some aspects have been described as features related to a method, it is obvious that such a description can also be considered as a description of corresponding features of a device or functionality of a device.

In the preceding detailed description, various features have been grouped together in examples in part to streamline the disclosure. This type of disclosure should not be interpreted as intending that the claimed examples have more features than are explicitly stated in each claim. Rather, as the following claims reflect, subject matter may be found in fewer than all of the features of a single disclosed example. Consequently, the following claims are hereby incorporated into the detailed description, and each claim may stand as its own separate example. While each claim may stand as its own separate example, it should be noted that although dependent claims in the claims refer back to a specific combination with one or more other claims, other examples also include a combination of dependent claims with the subject matter of any other dependent claim or a combination of any feature with other dependent or independent claims. Such combinations are encompassed unless it is stated that a specific combination is not intended. It is further intended that a combination of features of a claim with any other independent claim is also encompassed, even if that claim is not directly dependent on the independent claim.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A method for manufacturing a semiconductor device, comprising:
providing a layered structure of the semiconductor device, the layered structure comprising a first layer, the first layer comprising a III-V compound semiconductor material;
depositing a second layer on a main surface region of the first layer, such that the second layer comprises silicon and a doping material for the silicon, wherein depositing the second layer is performed using chemical vapor deposition or physical vapor deposition;
activating the second layer to form an ohmic contact between the first layer and the second layer,
wherein depositing the second layer is performed such that introducing the doping material into the silicon is performed during depositing the silicon on the main surface region of the first layer.

2. The method according to claim 1, wherein the III-V compound semiconductor material of the first layer is doped with a doping material, wherein an atomic density of the doping material in the first layer is between 10¹⁷ cm⁻³ and 10²³ cm⁻³ or between 10¹⁸ cm⁻³ and 10²¹ cm⁻³.

3. The method according to claim 1, wherein activating the second layer comprises irradiating the layered structure with electromagnetic radiation.

4. The method according to claim 1, wherein activating the second layer is performed by means of a laser scanning method.

5. The method according to claim 1, wherein activating the second layer comprises thermal heating of the second layer.

6. The method according to claim 1, wherein depositing the second layer is performed such that the silicon of the second layer is amorphous or polycrystalline.

7. The method according to claim 1, further comprising:
forming a contact structure on a main surface region of the second layer facing away from the first layer, wherein forming the contact structure comprises depositing one or several further layers on the main surface region of the second layer.

8. The method according to claim 1, wherein the doping material for the silicon comprises one or several of phosphorus, boron, antimony, magnesium, gallium, aluminum and arsenic.

9. The method according to claim 1, wherein depositing the second layer is performed such that a concentration of a doping material for the silicon in the second layer
is greater than 10¹⁵ cm⁻³ or greater than 10¹⁶ cm⁻³ or greater than 10¹⁷ cm⁻³, or
lies in a range between 10¹⁵ cm⁻³ and 10²³ cm⁻³ or between 10¹⁷ cm⁻³ and 10²³ cm⁻³.

10. The method according to claim 1,
wherein the III-V compound semiconductor material of the first layer comprises an n-type doping, and wherein the doping material of the second layer generates an n-type doping of the silicon, or
wherein the III-V compound semiconductor material of the first layer comprises a p-type doping, and wherein the doping material of the second layer generates a p-type doping of the silicon.

11. The method according to claim 1, wherein the method comprises forming the first layer as an active layer of the semiconductor device.

12. The method according to claim 1, wherein the method comprises forming the semiconductor device such that the first layer provides a conduit at least in an operative state of the semiconductor device.

13. The method according to claim 1, which is a microelectronic device, a power electronic device, or a micro-electromechanical system device.

14. A semiconductor device manufactured using the method according to claim 1.
